(19) United States
(12) Patent Application Publication
(10) Pub. No.: US 2023/0085944 A1
(43) Pub. Date: Mar. 23, 2023

(54) CORE PATCH WITH MATCHED PTH TO FLI PITCH FOR Z-DISAGGREGATION

(71) Applicant: Intel Corporation, Santa Clara, CA (US)

(72) Inventors: Bai NIE, Chandler, AZ (US); Brandon C. MARIN, Gilbert, AZ (US); Sandeep B. SANE, Chandler, AZ (US); Leonel ARANA, Phoenix, AZ (US); Srinivas V. PIETAMBARAM, Chandler, AZ (US); Tarek A. IBRAHIM, Mesa, AZ (US)

(21) Appl. No.: 17/482,843

(22) Filed: Sep. 23, 2021

(51) Int. Cl. H01L 23/498; H01L 23/538; H01L 25/065; H01L 23/00

(52) U.S. Cl. CPC H01L 23/49833; H01L 23/49822; H01L 23/5383; H01L 25/0655; H01L 24/16; H01L 2224/16227; H01L 2224/16235; H01L 2924/37001; H01L 25/0652

(57) ABSTRACT

Embodiments disclosed herein include electronic packages and methods of forming such packages. In an embodiment, an electronic package comprises a core, where the core comprises an organic material. In an embodiment, a via is provided through a thickness of the core. In an embodiment, a shell is around the via, where the shell comprises a magnetic material. In an embodiment, a mold layer is over the core, and a bridge is embedded in the mold layer. In an embodiment, a column is through the mold layer, where the column is aligned with the via.

### TECHNICAL FIELD

Embodiments of the present disclosure relate to electronic packages, and more particularly to electronic packages that are assembled with a disaggregated approach in order to improve manufacturing yield.

### BACKGROUND

As the complexity of electronic packaging increases, the layer count of the package also increases. As layer count rises, patterning yield becomes more critical. That is, for each extra layer, the risk of a patterning error in the package increases. This is particularly problematic with complex packages that include specialized layers, such as glass layers. The glass layer results in an increase in the packaging cost, due in part to the need for special handling equipment in order to minimize the risk of damage to the glass layer.

When a patterning error is present in such package architectures, the entire package must be scrapped or reworked. This is costly due to the increased handling and material costs driven by the glass layer. Even when there is no defect in the expensive glass layer, the entire package needs to be scrapped when yield issues arise in lower cost layers of the package.

### BRIEF DESCRIPTION OF THE DRAWINGS

FIG. 1A is a cross-sectional illustration of an electronic package with a glass patch with an embedded bridge coupled to low-cost package layers, in accordance with an embodiment.

FIG. 1B is a cross-sectional illustration of an electronic package with a glass patch coupled to low-cost package layers, in accordance with an embodiment.

FIG. 1C is a cross-sectional illustration of an electronic package with a glass patch coupled to a low-cost package layer, in accordance with an embodiment.

FIG. 2A is a cross-sectional illustration of a glass layer on a carrier, in accordance with an embodiment.

FIG. 2B is a cross-sectional illustration of the glass layer after buildup layers with an embedded bridge are formed over the glass layer, in accordance with an embodiment.

FIG. 2C is a cross-sectional illustration of the glass layer released from the carrier, in accordance with an embodiment.

FIG. 2D is a cross-sectional illustration of the glass layer substrate with first level interconnects (FLIs) and mid-level interconnects (MLIs), in accordance with an embodiment.

FIG. 2E is a cross-sectional illustration of the glass layer substrate being assembled with an organic core substrate, and a laminate core substrate, in accordance with an embodiment.

FIG. 3A is a cross-sectional illustration of a glass layer on a carrier, in accordance with an embodiment.

FIG. 3B is a cross-sectional illustration of the glass layer after buildup layers are formed over the glass layer, in accordance with an embodiment.

FIG. 3C is a cross-sectional illustration of the glass layer after it is released from the carrier, in accordance with an embodiment.

FIG. 3D is a cross-sectional illustration of the glass layer after FLIs and MLIs are formed over the top and bottom surfaces, in accordance with an embodiment.

FIG. 3E is a cross-sectional illustration of the glass layer substrate being assembled with an organic core substrate, and a laminate core substrate, in accordance with an embodiment.

FIG. 4 is a cross-sectional illustration of an electronic system with a glass patch coupled to package substrate layers and a board, in accordance with an embodiment.

FIG. 5A is a cross-sectional illustration of an organic core patch with an embedded bridge, in accordance with an embodiment.

FIG. 5B is a cross-sectional illustration of an organic core patch with an embedded bridge with through substrate vias, in accordance with an embodiment.

FIG. 6A is a cross-sectional illustration of an organic core patch, in accordance with an embodiment.

FIG. 6B is a cross-sectional illustration of the organic core patch after mold layers and an embedded bridge are disposed over the organic core, in accordance with an embodiment.

FIG. 6C is a cross-sectional illustration of the organic core patch coupled to a package substrate, in accordance with an embodiment.

FIG. 7 is a cross-sectional illustration of an electronic system with an organic core patch coupled to a package substrate and a board, in accordance with an embodiment.

FIG. 8 is a schematic of a computing device built in accordance with an embodiment.

### EMBODIMENTS OF THE PRESENT DISCLOSURE

Described herein are electronic packages that are assembled with a disaggregated approach in order to improve manufacturing yield, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, the increased complexity of electronic packages has led to issues with low yielding assembly processes. The low yielding processes are particularly problematic in advanced packaging architectures that use costly non-organic layers, such as glass layers. Glass layers are desired in the electronic package because it enables low bump thickness variation (rBTV) and low bump-to-bump (BtB) true position (TP) error for the first level interconnects (FLIs). Glass layers are especially useful for packaging substrates that include embedded bridges due to the need for low rBTV and BtB TP error in such architectures.

Currently, the glass layers are integrated with the remainder of the packaging substrate layers in a monolithic structure. When fabricated in such a design, any defects in the package substrate layers will result in the need to scrap the entire electronic package. Due to the high cost of glass layers, this is particularly problematic. Accordingly, embodiments disclosed herein include Z-disaggregation. Instead of a monolithic structure, a glass patch is formed that can be stitched to underlying layers. For example, the glass patch may be stitched to an organic core layer, and the core layer may be stitched to a laminate stack-up. Separating the layers in such a manner allows for only known good modules to be used. Since only known good modules make it to the package substrate, the yield is significantly improved, and the waste of expensive glass patches is avoided.

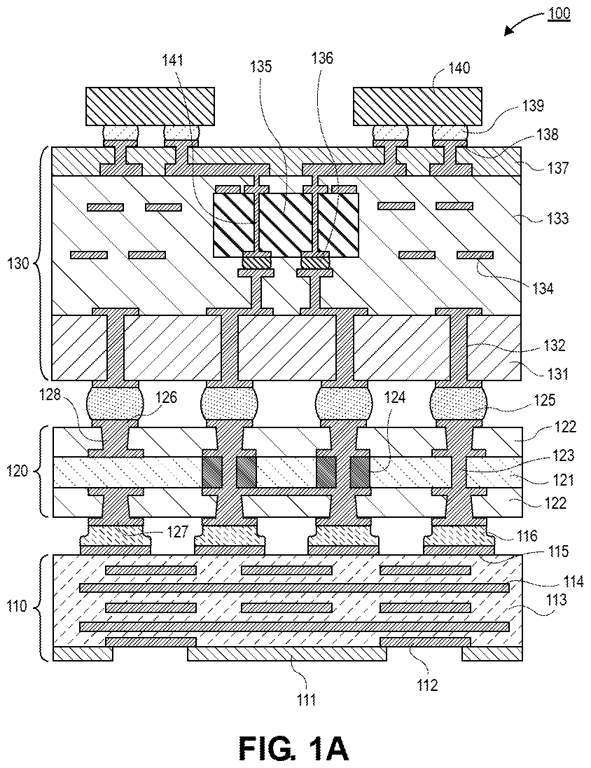

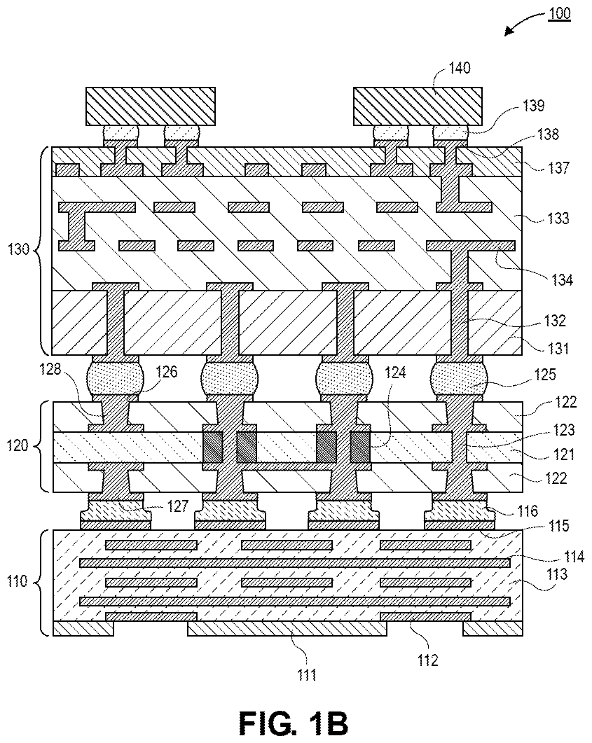

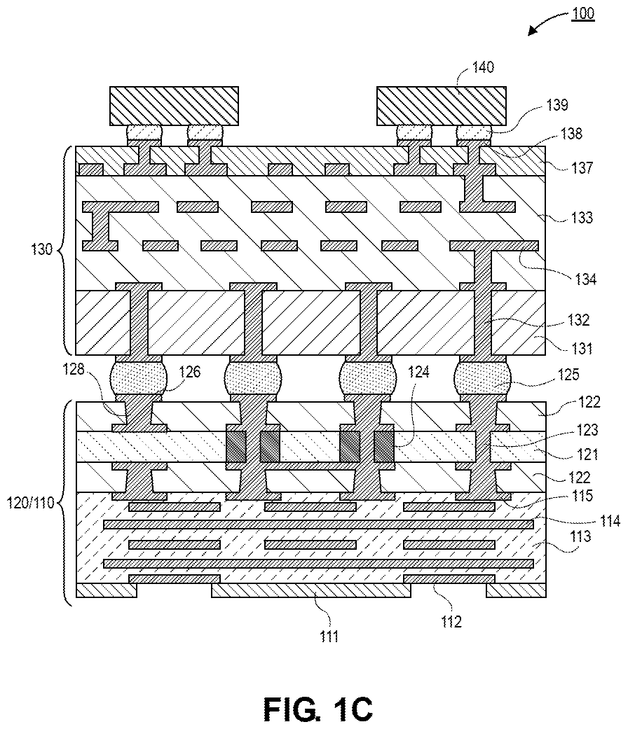

Referring now to FIG. 1A, a cross-sectional illustration of an electronic package 100 is shown, in accordance with an embodiment. In an embodiment, the electronic package 100 comprises a plurality of substrate modules 110, 120, and 130 that are stitched together. Substrate module 110 may be laminate core, such as a stacked via laminate core (SVLC). Substrate module 120 may be an organic core substrate. Substrate module 130 may be a glass patch. In an embodiment, the substrate module 110 may be stitched to the substrate module 120 by first solder 116, and the substrate module 120 may be stitched to the substrate module 130 by second solder 125. In an embodiment, the first solder 116 may have a different composition than the second solder 125. As such, the first solder 116 may have a different reflow temperature than the second solder 125.

Since the substrate modules 110, 120, and 130 are stitched together (instead of being a monolithic structure), only known good modules 110, 120, 130 may be integrated into the electronic package 100. As such, yield issues in low cost substrate modules (such as the substrate module 110 and the substrate module 120) will not result in the high cost substrate module (such as substrate module 130 with a glass layer 131) being wasted. Accordingly, overall yield can be improved and result in a reduction in the cost of the electronic package 100.

In an embodiment, the substrate module 110 may comprise a plurality of laminated dielectric layers 113. Conductive routing 114 (e.g., traces, vias, pads) may be provided in the dielectric layer 113. Second level interconnect (SLI) pads 112 may be provided at a bottom of the substrate module 110. The SLI pads 112 may be surrounded by a solder resist layer 111. In an embodiment, MLI pads 115 may be provided at a top surface of the substrate module 110. The MLI pads 115 may be contacted by the first solder 116.

In an embodiment, the substrate module 120 may comprise an organic core 121. Dielectric layers 122 may be provided above and/or below the core 121. In an embodiment, MLI pads 127 may be provided on the bottom of the substrate module 120. The MLI pads 127 are coupled to the MLI pads 115 by the first solder 116. In an embodiment, electrical paths through the substrate module 120 may be provided by vias 128 through the dielectric layers 122 and through core vias 123 through the core 121. In some embodiments, through core vias 123 may be surrounded by a shell, such as a magnetic shell. Such through core vias 123 may be used for power circuitry (e.g., as part of a voltage regulator) for overlying dies 140. In an embodiment, MLI pads 126 may be provided over the top dielectric layers 122. The MLI pads 126 may be in contact with the second solder 125.

In an embodiment, the substrate module 130 is a glass patch. That is, a glass layer 131 may be provided at a bottom of the substrate module 130, and dielectric layers 133 may be provided over the glass layer 131. In an embodiment, through glass vias 132 may be provided through the glass layer 131. In the illustrated embodiment, the sidewalls of the through glass vias 132 are substantially vertical. However, in other embodiments, the sidewalls of the through glass vias 132 may be tapered or the through glass vias may have an hourglass shaped cross-section. In an embodiment, the through glass vias 132 are coupled to electrical routing 134 (e.g., traces, pads, vias, etc.) embedded in the dielectric layers 133.

In an embodiment, a bridge 135 may be embedded in the dielectric layers 133. A backside of the bridge 135 may be coupled to the conductive routing 134 by solder balls 136. Through substrate vias 141 may pass through a thickness of the bridge 135. In an embodiment, the bridge 135 comprises a semiconductor material, such as silicon. The bridge 135 may be an active device (e.g., including transistors and the like), or the bridge 135 may be passive. The bridge 135 provides high density electrical routing in order to communicatively couple a first die 140 to a second die 140.

In an embodiment, a solder resist layer 137 is provided over the dielectric layers 133. FLI pads 138 may be provided over the solder resist layer 137. In an embodiment, an FLI 139 couples the dies 140 to the FLI pads 138. In the illustrated embodiment, the FLIs 139 are shown as a solder ball, but it is to be appreciated that other FLI architectures may be used. For example, hybrid bonding, may be used in some embodiments. In an embodiment, the dies 140 may be any type of die. For example, the dies 140 may be processors, graphics processors, memory dies, or any other type of semiconductor die.

Referring now to FIG. 1B, a cross-sectional illustration of an electronic package 100 is shown, in accordance with an additional embodiment. In an embodiment, the electronic package 100 in FIG. 1B may be substantially similar to the electronic package 100 in FIG. 1A, with the exception of the architecture of the substrate module 130. That is, the electronic package 100 may include a first substrate module 110, a second substrate module 120, and a third substrate module 130 that are all stitched together to provide Z-disaggregation. However, instead of providing an embedded bridge, the substrate module 130 includes high density package (HDP) routing. That is, the conductive routing 134 in the dielectric layers 133 may provide the communicative coupling between the two dies 140.

Referring now to FIG. 1C, a cross-sectional illustration of an electronic package 100 is shown, in accordance with an embodiment. The electronic package 100 in FIG. 1C may be substantially similar to the electronic package 100 in FIG. 1B, with the exception of the substrate module 110 being integrated with the substrate module 120. Instead of being stitched together by a solder or the like, the substrate module 110 is laminated over the substrate module 120. For example, pad 115 in the dielectric layers 113 is directly contacted by a via 128 in the dielectric layer 122. While shown with different shading, it is to be appreciated that dielectric layer 122 may be the same material as the dielectric layer 113. Additionally, it is to be appreciated that a combined substrate module 110 and substrate module 120 can also be used in instances with a bridge die in the substrate module 130, similar to the embodiment shown in FIG. 1A.

Such an embodiment may result in there being a reduction in the complexity of the package 100 assembly. Instead of needing a pair of solders with different reflow temperatures, a single solder 125 is needed to couple the substrate module 130 to the combined substrate modules 120/110. Additionally, the reduction of a solder layer may decrease the Z-height of the electronic package 100.

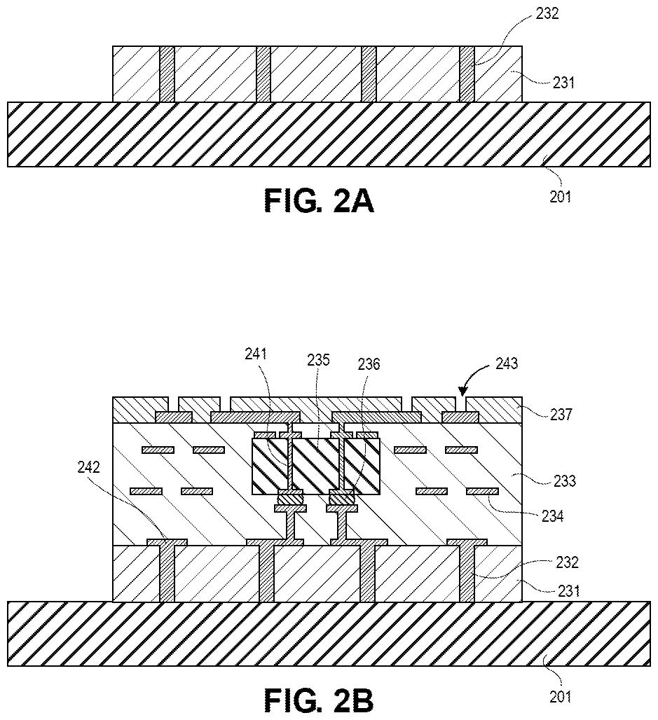

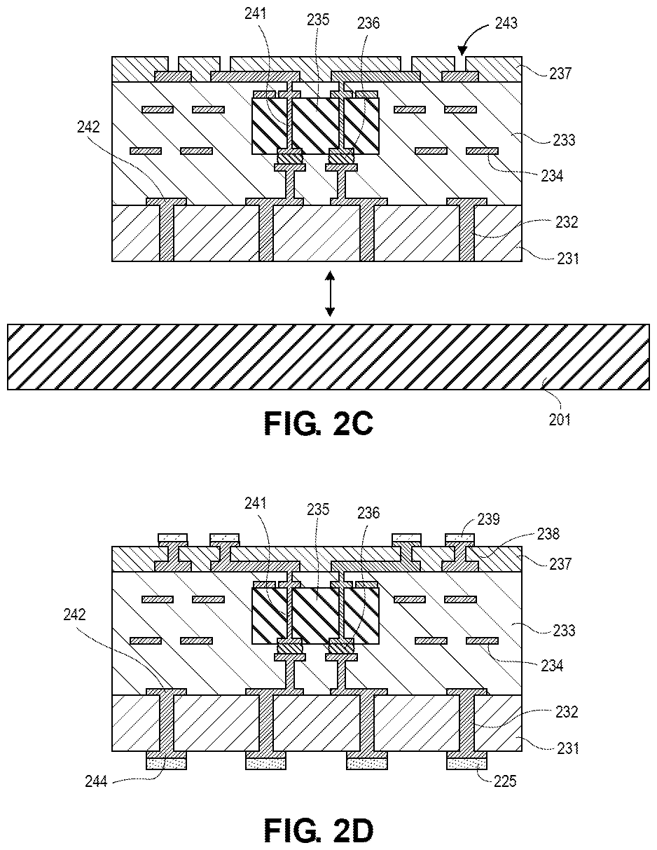

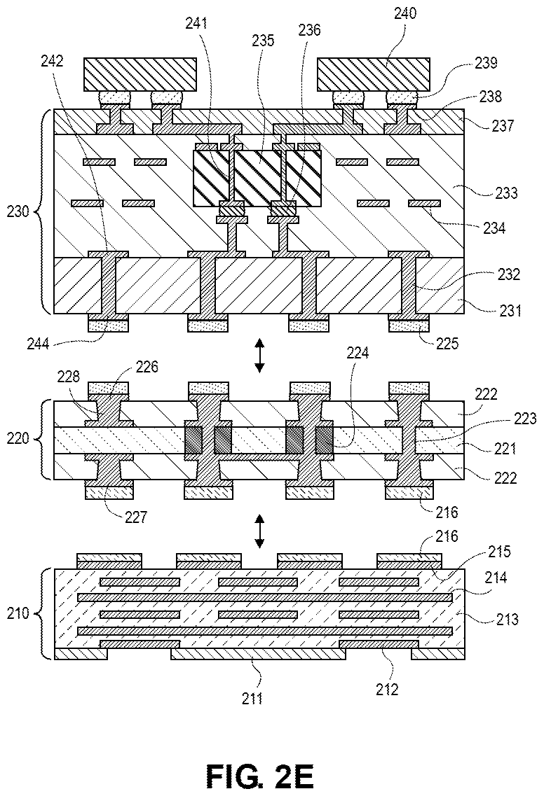

Referring now to FIGS. 2A-2E, a series of cross-sectional illustrations depicting a process for forming an electronic package is shown, in accordance with an embodiment. In an embodiment, the electronic package assembled in FIGS. 2A-2E may be substantially similar to the electronic package 100 in FIG. 1A.

Referring now to FIG. 2A, a cross-sectional illustration of a glass layer 231 over a carrier 201 is shown, in accordance with an embodiment. In an embodiment, the glass layer 231 may comprise through glass vias (TGVs) 232. The TGVs 232 may be formed in the glass layer 231 before the glass layer 231 is attached to the carrier 201. In the illustrated embodiment, the TGVs 232 have vertical sidewalls. In other embodiments, the TGVs 232 may have tapered sidewalls, or the TGVs 232 may have an hourglass shaped cross-section. In an embodiment, the TGVs 232 may be formed with a laser assisted etching process. That is, laser exposure may drive a morphological change in the glass layer 231 that reduces the resistance to an etchant.

In an embodiment, the glass layer 231 is adhered to the carrier 201 by an adhesive (not shown). The adhesive may be a laser activated adhesive. Laser activated adhesives may release the glass layer 231 when exposed to a laser. For example, the carrier 201 may also be a glass layer, and the laser can pass through the carrier 201 to reach the adhesive.

In an embodiment, the carrier 201 and the glass layer 231 may have different form factors. For example, the carrier 201 may have a panel level form factor, and the glass layer 231 may have a smaller form factor. In some embodiments, the glass layer 231 may have a quarter-panel form factor. In other embodiments, the glass layer 231 may have a unit level form factor.

Referring now to FIG. 2B, a cross-sectional illustration of the glass layer 231 after redistribution layers 233 are provided over the glass layer 231 is shown, in accordance with an embodiment. In an embodiment, the redistribution layers 233 may comprise conductive routing 234 (e.g., pads, traces, vias, etc.). In an embodiment, the conductive routing 234 couples the TGVs 232 to pads over the topmost redistribution layer 233. The topmost pads may be covered with a solder resist layer 237. The solder resist layer 237 may include openings 243 to expose the topmost pads.

In an embodiment, a bridge 235 is embedded in the redistribution layers 233. In an embodiment, a backside of the bridge 235 is coupled to the routing 234 by solder balls 236. However, in some embodiments, the backside of the bridge 235 may not be electrically coupled to any features. In an embodiment, the backside of the bridge 235 may be coupled to pads 242 over the TGVs 232. The bridge 235 may also include through substrate vias 241 in some embodiments. In other embodiments the bridge 235 may not include through substrate vias 241. In an embodiment, the bridge 235 may be a semiconductor substrate, such as silicon. The bridge 235 may be a passive substrate, or the bridge 235 may be an active substrate (e.g., including transistors or the like). In an embodiment, the bridge 235 provides high density routing in order to communicatively couple a pair of dies (added in a subsequent processing operation) together.

Referring now to FIG. 2C, a cross-sectional illustration of the glass layer 231 after the carrier 201 is removed is shown, in accordance with an embodiment. In an embodiment, the glass layer 231 is released from the carrier 201 by exposing an adhesive layer between the glass layer 231 and the carrier 201 (not shown) to a laser. In other embodiments, other adhesive types may be used. For example, the adhesive may be a temperature dependent adhesive or the like.

Referring now to FIG. 2D, a cross-sectional illustration of the glass layer 231 after FLI and MLI interconnects are formed is shown, in accordance with an embodiment. In an embodiment, MLI pads 244 may be formed over a bottom of the TGVs 232. The pads 244 may be plated with a solder 225. In an embodiment, FLI pads 238 may be formed over the solder resist layer 237. An FLI solder 239 may be plated over the FLI pads 238.

In an embodiment, the MLI pads 244 and the FLI pads 238 may be formed with any process typical of semiconductor processing. For example, the plating process may include a seed layer deposition with a resist layer disposed over the seed layer. The resist layer may be patterned to form openings for the MLI pads 244 or the FLI pads 238. Copper may then be plated to form the MLI pads 244 or the FLI pads 238. In an embodiment, the solder 225 or 239 is also plated. The resist layer is then stripped and the seed layer is etched.

Referring now to FIG. 2E, a cross-sectional illustration of the assembly process is shown, in accordance with an embodiment. As shown, a set of substrate modules 210, 220, and 230 are stitched together (as indicated by the arrows). In an embodiment, the first substrate module 210 is attached to the second substrate module 220 with solder 216. A second solder 225 couples the second substrate module 220 to the third substrate module 230. In an embodiment, the solder 216 may have a different reflow temperature than the solder 225.

In an embodiment, the first substrate module 210 may comprise a plurality of laminated dielectric layers 213. Conductive routing 214 is provided through the dielectric layers 213 to couple pads 215 to SLI pads 212. SLI pads 212 may be surrounded by a solder resist 211.

In an embodiment, the second substrate module 220 may comprise a core 221. Dielectric layers 222 may be provided above and below the core 221. In an embodiment, a MLI pad 227 is provided below the core 221 and is covered by the solder 216. MLI pads 226 are provided over the core 221 and are covered by solder 225. In an embodiment, pads 227 may be coupled to pads 226 through vias 228 through the dielectric layers 222 and through core vias 223 through the core 221. In some embodiments, one or more of the through core vias 223 may be surrounded by a shell 224 that comprises a magnetic material.

In an embodiment, the third substrate module 230 may be substantially similar to the structure shown in FIG. 2D. As shown, dies 240 may be attached to pads 238 by solder 239. That is, the dies 240 may be attached before stitching together the substrate modules 210, 220, and 230. In other embodiments, the dies 240 may be attached after stitching together the substrate modules 210, 220, and 230.

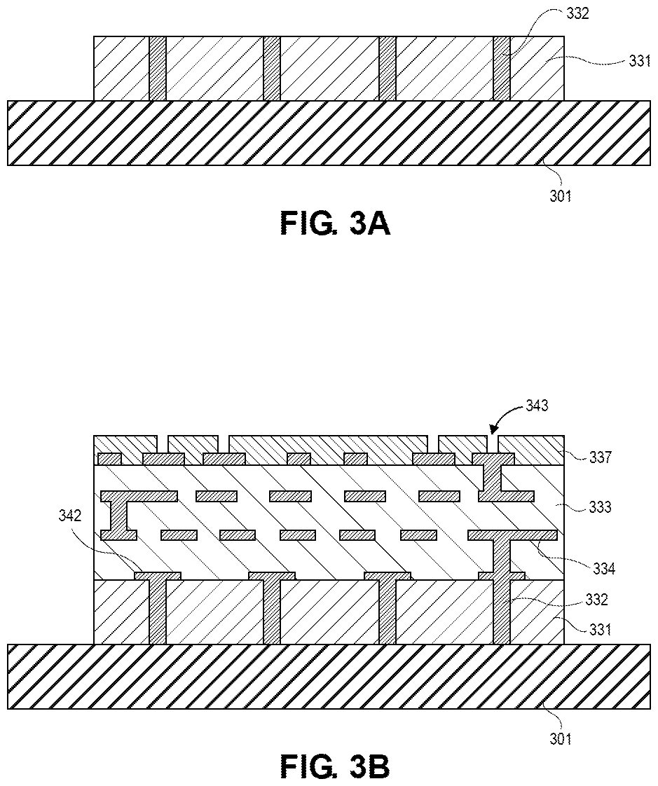

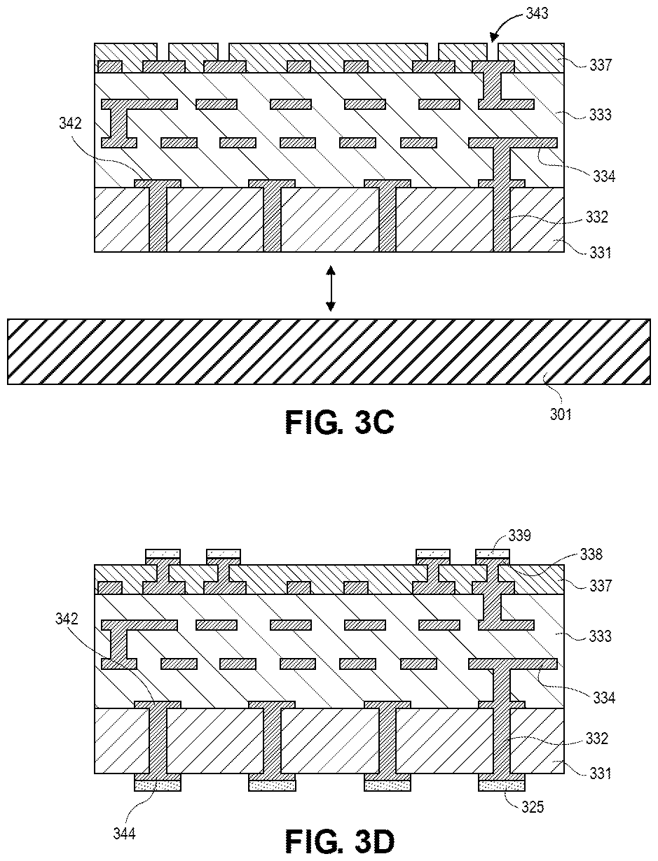

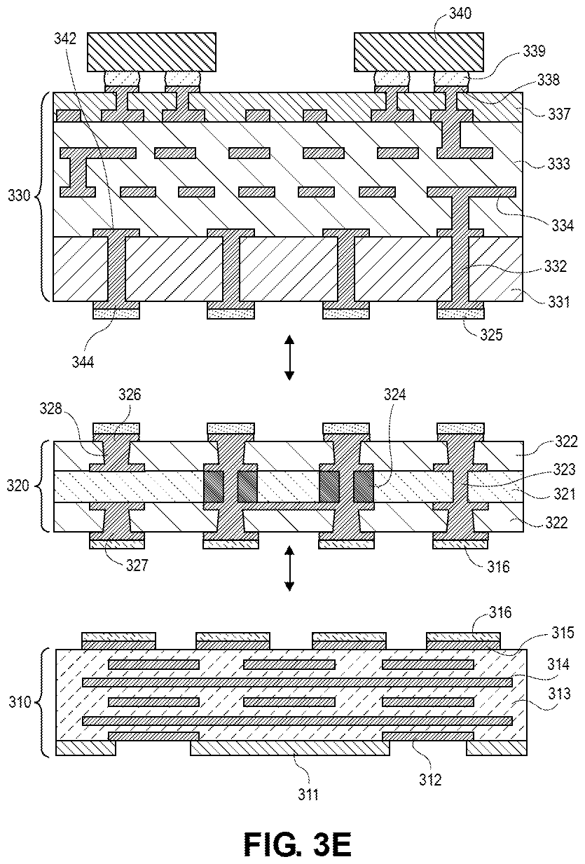

Referring now to FIGS. 3A-3E, a series of cross-sectional illustrations depicting a process for forming an electronic package is shown, in accordance with an embodiment. In an embodiment, the electronic package assembled in FIGS. 3A-3E may be substantially similar to the electronic package 100 in FIG. 1B.

Referring now to FIG. 3A, a cross-sectional illustration of a glass layer 331 over a carrier 301 is shown, in accordance with an embodiment. In an embodiment, the glass layer 331 may comprise through glass vias (TGVs) 332. The TGVs 332 may be formed in the glass layer 331 before the glass layer 331 is attached to the carrier 301. In the illustrated embodiment, the TGVs 332 have vertical sidewalls. In other embodiments, the TGVs 332 may have tapered sidewalls, or the TGVs 332 may have an hourglass shaped cross-section. In an embodiment, the TGVs 332 may be formed with a laser assisted etching process. That is, laser exposure may drive a morphological change in the glass layer 331 that reduces the resistance to an etchant.

In an embodiment, the glass layer 331 is adhered to the carrier 301 by an adhesive (not shown). The adhesive may be a laser activated adhesive. Laser activated adhesives may release the glass layer 331 when exposed to a laser. For example, the carrier 301 may also be a glass layer, and the laser can pass through the carrier 301 to reach the adhesive.

In an embodiment, the carrier 301 and the glass layer 331 may have different form factors. For example, the carrier 301 may have a panel level form factor, and the glass layer 331 may have a smaller form factor. In some embodiments, the glass layer 331 may have a quarter-panel form factor. In other embodiments, the glass layer 331 may have a unit level form factor.

Referring now to FIG. 3B, a cross-sectional illustration of the glass layer 331 after redistribution layers 333 are provided over the glass layer 331 is shown, in accordance with an embodiment. In an embodiment, the redistribution layers 333 may comprise conductive routing 334 (e.g., pads, traces, vias, etc.). In an embodiment, the conductive routing 334 and pads 342 couple the TGVs 332 to pads over the topmost redistribution layer 333. The topmost pads may be covered with a solder resist layer 337. The solder resist layer 337 may include openings 343 to expose the topmost pads.

Referring now to FIG. 3C, a cross-sectional illustration of the glass layer 331 after the carrier 301 is removed is shown, in accordance with an embodiment. In an embodiment, the glass layer 331 is released from the carrier 301 by exposing an adhesive layer between the glass layer 331 and the carrier 301 (not shown) to a laser. In other embodiments, other adhesive types may be used. For example, the adhesive may be a temperature dependent adhesive or the like.

Referring now to FIG. 3D, a cross-sectional illustration of the glass layer 331 after FLI and MLI interconnects are formed is shown, in accordance with an embodiment. In an embodiment, MLI pads 344 may be formed over a bottom of the TGVs 332. The pads 344 may be plated with a solder 325. In an embodiment, FLI pads 338 may be formed over the solder resist layer 337. An FLI solder 339 may be plated over the FLI pads 338.

In an embodiment, the MLI pads 344 and the FLI pads 338 may be formed with any process typical of semiconductor processing. For example, the plating process may include a seed layer deposition with a resist layer disposed over the seed layer. The resist layer may be patterned to form openings for the MLI pads 344 or the FLI pads 338. Copper may then be plated to form the MLI pads 344 or the FLI pads 338. In an embodiment, the solder 325 or 339 is also plated. The resist layer 337 is then stripped and the seed layer is etched.

Referring now to FIG. 3E, a cross-sectional illustration of the assembly process is shown, in accordance with an embodiment. As shown, a set of substrate modules 310, 320, and 330 are stitched together (as indicated by the arrows). In an embodiment, the first substrate module 310 is attached to the second substrate module 320 with solder 316. A second solder 325 couples the second substrate module 320 to the third substrate module 330. In an embodiment, the solder 316 may have a different reflow temperature than the solder 325.

In an embodiment, the first substrate module 310 may comprise a plurality of laminated dielectric layers 313. Conductive routing 314 is provided through the dielectric layers 313 to couple pads 315 to SLI pads 312. SLI pads 312 may be surrounded by a solder resist 311.

In an embodiment, the second substrate module 320 may comprise a core 321. Dielectric layers 322 may be provided above and below the core 321. In an embodiment, a MLI pad 327 is provided below the core 321 and is covered by the solder 316. MLI pads 326 are provided over the core 321 and are covered by solder 325. In an embodiment, pads 327 may be coupled to pads 326 through vias 328 through the dielectric layers 322 and through core vias 323 through the core 321. In some embodiments, one or more of the through core vias 323 may be surrounded by a shell 324 that comprises a magnetic material.

In an embodiment, the third substrate module 330 may be substantially similar to the structure shown in FIG. 3D. As shown, dies 340 may be attached to pads 338 by solder 339. That is, the dies 340 may be attached before stitching together the substrate modules 310, 320, and 330. In other embodiments, the dies 340 may be attached after stitching together the substrate modules 310, 320, and 330.

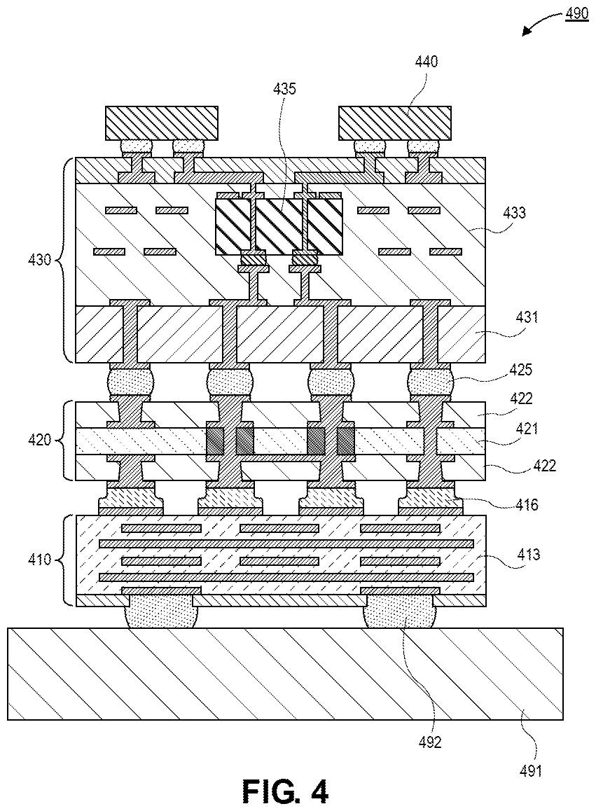

Referring now to FIG. 4, a cross-sectional illustration of an electronic system 490 is shown, in accordance with an embodiment. In an embodiment, the electronic system 490 may comprise a board 491, such as a printed circuit board (PCB). The board 491 may be coupled to a first substrate module 410 by SLI interconnects 492. For example, the SLI interconnects 492 may be solder balls or the like.

In an embodiment, the electronic system 490 may comprise a plurality of substrate modules that are stitched together. For example substrate module 410 is coupled to substrate module 420 by solder 416, and substrate module 420 is coupled to substrate module 430 by solder 425.

In an embodiment, the substrate module 410 may comprise conductive routing embedded in a plurality of dielectric layers 413. The substrate module 410 may comprise an organic core 421 with dielectric layers 422 above and below the core 421. In an embodiment, the substrate module 430 may comprise a glass layer 431 with buildup layers 433 over the glass layer 431. A bridge 435 may be embedded in the buildup layers 433. A pair of dies 440 may be communicatively coupled together by the bridge 435.

In the illustrated embodiment, the substrate modules 410, 420, and 430 are substantially similar to the substrate modules 110, 120, and 130 in FIG. 1A. However, it is to be appreciated that substantially similar electronic systems 490 may be formed using electronic packages similar to what is shown in FIG. 1B, in FIG. 1C, or in accordance with any embodiment disclosed herein.

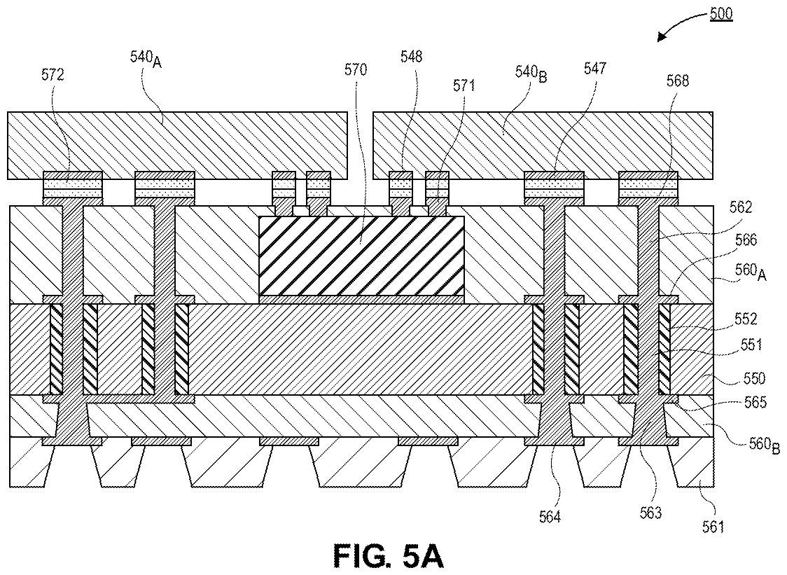

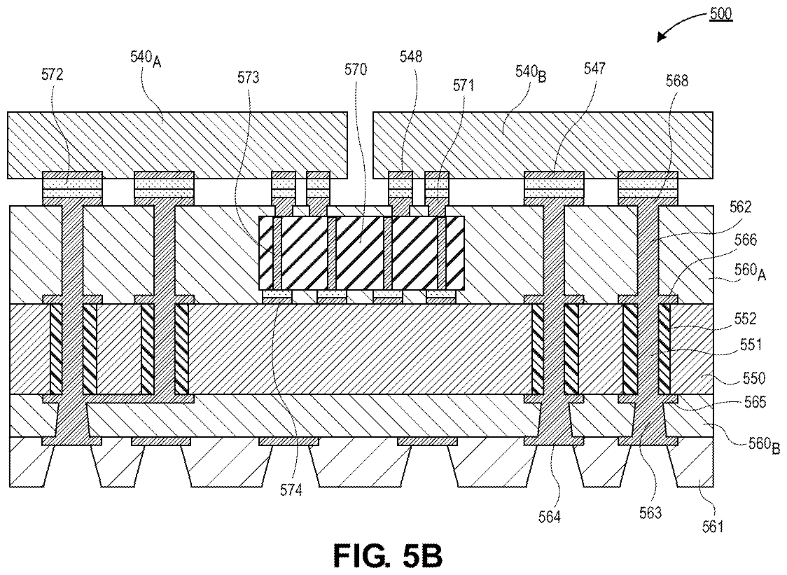

Referring now to FIGS. 5A and 5B cross-sectional illustrations of organic core patches are shown, in accordance with additional embodiment. In an embodiment, the organic core patches include a core material with standard organic core materials. For example, the cores may comprise a dielectric material with fiber reinforcement. The organic core patches allow for yield loss susceptible architectures (e.g., layers that include an embedded bridge) to be isolated from other packaging layers. For example, the organic core patches can be attached to underlying package substrates to enable Z-disaggregation.

Referring now to FIG. 5A, a cross-sectional illustration of an electronic package 500 is shown, in accordance with an embodiment. In an embodiment, the electronic package 500 may be considered an organic core patch. That is, the electronic package comprises a core layer 550. The core layer 550 may be a dielectric material. In some instances the core layer 550 includes fiber reinforcement. In an embodiment, mold layers 560_{A} and 560_{B} may be provided above and below the core layer 550. The mold layers 560_{A} and 560_{B} may comprise a mold material, or the layers 560_{A} and 560_{B} may be typical dielectric buildup layers in some embodiments.

In an embodiment, the core layer 550 may comprise through core vias 551. In an embodiment, the through core vias 551 may be formed with laser drilling or mechanical drilling processes. In an embodiment, the through core vias 551 may be surrounded by a shell 552. The shell 552 may comprise a magnetic material in some embodiments. The magnetic material for the shell 552 may be used when the through core vias 551 are used for power delivery purposes (e.g., inductors or the like). In an embodiment, the bottom side of the through core vias 551 may be coupled to MLI pads 564 by vias 563 and pads 565 in the bottom mold layer 560_{B}. The MLI pads 564 may be covered by a solder resist layer 561.

In an embodiment, the pads 566 over the through core vias 551 may be coupled to FLI pads 568 by vertical columns 562 through the top mold layer 560_{A}. In an embodiment, the vertical columns 562 are aligned with the underlying through core vias 551. As such, the path between the inductors (i.e., the through core vias 551 and the magnetic shells 552) and the overlying dies 540 is minimized. This increases power performance of the electronic package 500. In an embodiment, the FLI pads 568 are coupled to the pads 547 on the dies 540_{A} and 540_{B} by solder 572 or other FLI architectures.

In an embodiment, the electronic package 500 may further comprise a bridge 570 embedded in the top mold layer 560_{A}. The bridge 570 may be coupled to FLI pads 571. The FLI pads 571 are coupled to pads 548 on the dies 540_{A} and 540_{B} by the solder 572 or the like. In an embodiment, the bridge 570 communicatively couples the first die 540_{A} to the second die 540_{B}. In some embodiments, the bridge 570 is a passive die, and in other embodiments the bridge 570 is an active die. The bridge 570 may comprise a semiconductor material, such as silicon.

Referring now to FIG. 5B, a cross-sectional illustration of an electronic package 500 is shown, in accordance with an additional embodiment. The electronic package 500 in FIG. 5B may be substantially similar to the electronic package 500 in FIG. 5A, with the exception of the construction of the embedded bridge 570. As shown in FIG. 5B, the bridge 570 may further comprise through substrate vias 573. In some embodiments, the bridge 570 is a silicon bridge and the through substrate vias 573 may be referred to as through silicon vias 573. However, in other embodiments the bridge 570 may include an organic substrate. The through substrate vias 573 may be coupled to backside pads 574 that are on the core layer 550. As such, electrical connections may be made vertically through the bridge 570 in some embodiments.

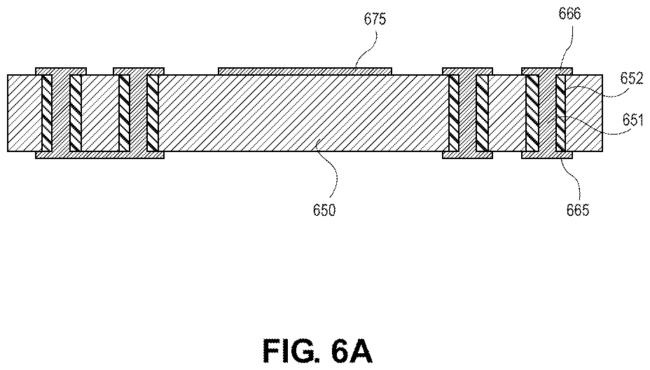

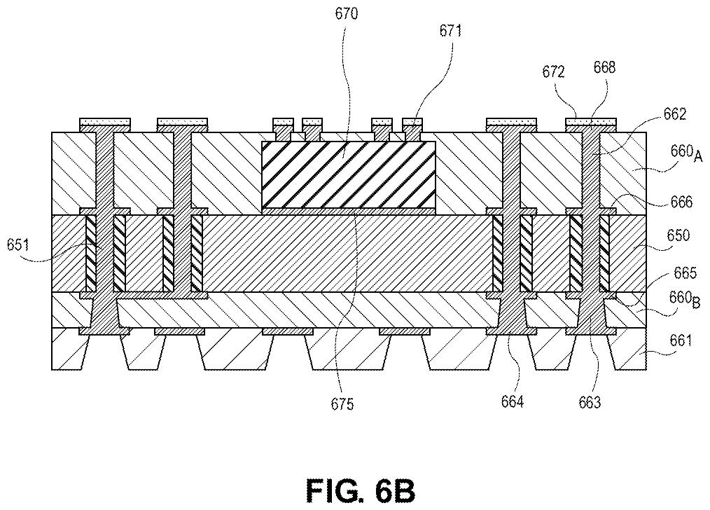

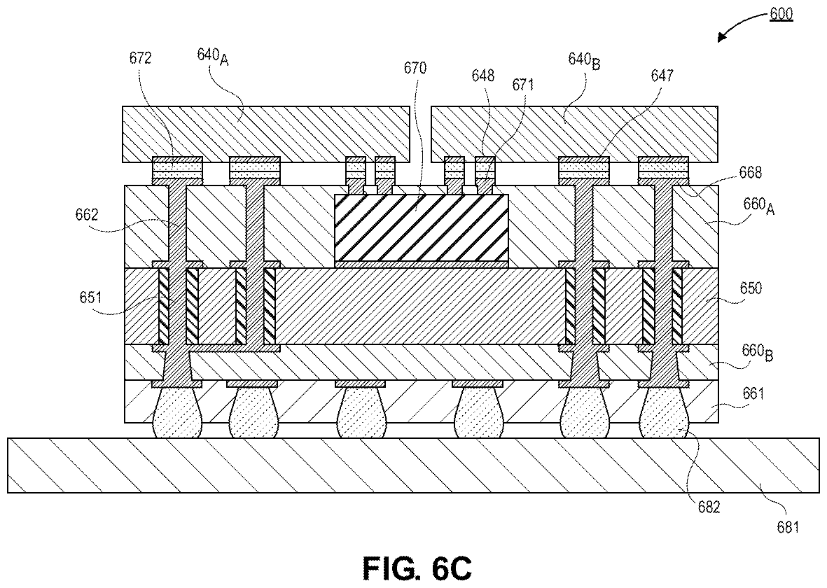

Referring now to FIGS. 6A-6C, a series of cross-sectional illustrations depicting a process for assembling an electronic package is shown, in accordance with an embodiment. In an embodiment, the electronic package formed in FIGS. 6A-6C may be substantially similar to the electronic package 500 in FIG. 5A. However, it is to be appreciated that the bridge may be substituted for a bridge similar to the one shown in FIG. 5B as well.

Referring now to FIG. 6A, a cross-sectional illustration of a core 650 is shown, in accordance with an embodiment. In an embodiment, the core 650 may comprise a dielectric material that is reinforced with fibers (e.g., glass fibers). In an embodiment, through core vias 651 may be formed through the core 650. In an embodiment, the through core vias 651 may be surrounded by a shell 652. The shells 652 may comprise a magnetic material. The use of a magnetic material for the shells 652 may be particularly beneficial when the through core vias 651 are used for power delivery applications (e.g., as inductors). In an embodiment, pads 666 may be provided over the through core vias 651 and pads 665 may be provided below the through core vias 651. In an embodiment, a pad 675 may be provided over the core 650. The pad 675 may be used in the placement of the bridge in a subsequent processing operation. In an embodiment, the pad 675 may have a footprint that is larger than a footprint of the bridge (e.g., tens of microns larger than the footprint of the bridge).

Referring now to FIG. 6B, a cross-sectional illustration of the structure after further assembly is shown, in accordance with an embodiment. In an embodiment, a mold layer 660_{A} is applied over the core 650 and a mold layer 660_{B} is applied under the core 650. In some embodiments, the mold layers 660_{A} and 660_{B} are molding materials. However, in other embodiments, layers 660_{A} and 660_{B} may be buildup film layers. In an embodiment, columns 662 may pass through the mold layer 660_{A} and couple FLI pads 668 to pads 666. In an embodiment, the columns 662 are aligned over the through core vias 651. Solder 672 may be plated over the FLI pads 668. On the bottom side of the core 650, vias 663 may pass through the mold layer 660_{B} to electrically couple the pads 665 to MLI pads 664. In an embodiment, the MLI pads 664 may be surrounded by a solder resist layer 661.

In an embodiment, a bridge 670 may be placed on the pad 675. The bridge 670 may be coupled to FLI pads 671 by vias. In an embodiment, the bridge 670 is shown without through substrate vias. However, in other embodiments, the bridge 670 may include through substrate vias, similar to the embodiment shown in FIG. 5B.

Referring now to FIG. 6C, a cross-sectional illustration of an electronic package 600 is shown, in accordance with an embodiment. As shown, a pair of dies 640_{A} and 640_{B} are coupled to the FLI pads 668 and 671 by solder 672 or the like. In an embodiment, dies 640_{A} and 640_{B} may have bridge pads 648 and regular pads 647. In an embodiment, the core patch may be coupled to an underlying package substrate 681 by MLIs 682.

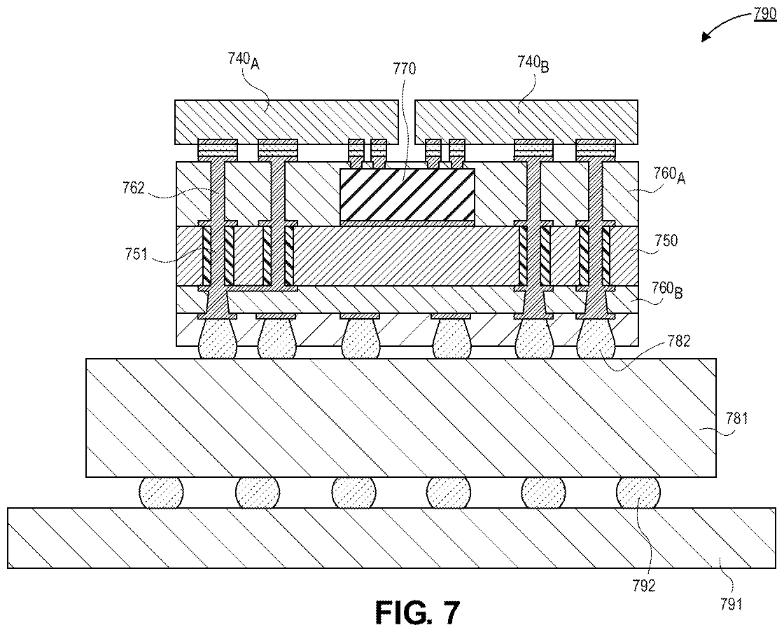

Referring now to FIG. 7, a cross-sectional illustration of an electronic system 790 is shown, in accordance with an embodiment. In an embodiment, the electronic system 790 comprises a board, such as a PCB. In an embodiment, a package substrate 781 is coupled to the board by SLIs 792. The SLIs 792 are shown as solder balls, but it is to be appreciated that any SLI architecture may be used (e.g., sockets or the like). In an embodiment, the package substrate 781 is coupled to a core patch by MLIs 782.

In an embodiment, the core patch comprises an organic core 750. Mold layers 760_{A} and 760_{B} may be formed over the core 750. In an embodiment, through core vias 751 pass through a thickness of the core 750. Columns 762 are provided through the mold layers 760_{A}. The columns 762 are aligned with the underlying through core vias 751. In an embodiment, a bridge 770 may be embedded in the mold layer 760_{A}. The bridge 770 may communicatively couple the first die 740_{A} to the second die 740_{B}. In an embodiment, the bridge 770 may be without through substrate vias. In other embodiments, through substrate vias may pass through the bridge 770, similar to the embodiment shown in FIG. 5B.

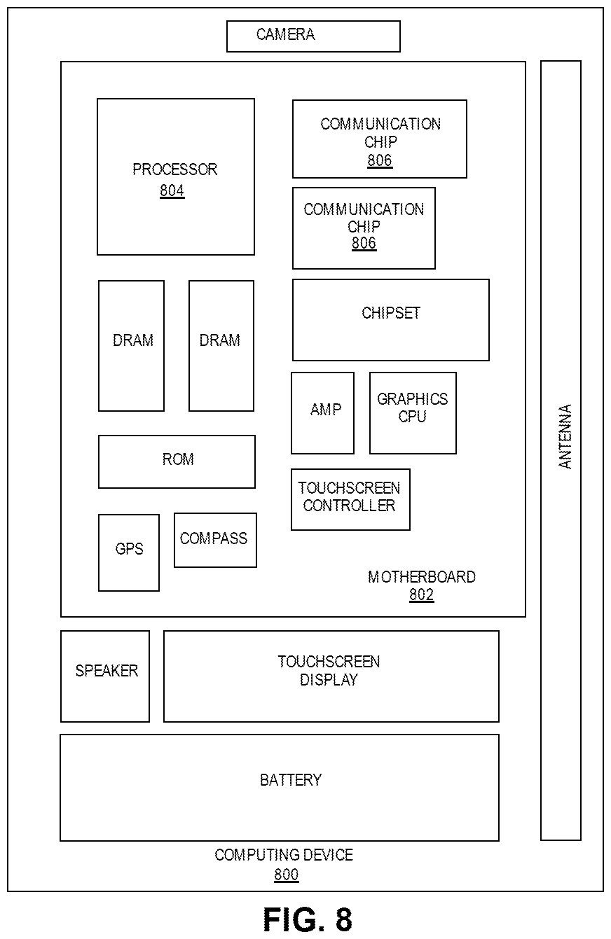

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package that comprises a plurality of substrate modules that are stitched together to form a vertically disaggregated electronic package, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic package that comprises a plurality of substrate modules that are stitched together to form a vertically disaggregated electronic package, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a core, wherein the core comprises an organic material; a via through a thickness of the core; a shell around the via, wherein the shell comprises a magnetic material; a mold layer over the core; a bridge embedded in the mold layer; and a column through the mold layer, wherein the column is aligned with the via.

Example 2: the electronic package of Example 1, wherein the bridge comprises through substrate vias.

Example 3: the electronic package of Example 2, wherein a backside of the bridge is coupled to a plurality of pads on a surface of the core.

Example 4: the electronic package of Examples 1-3, further comprising: a second mold layer below the core; and a solder resist layer on the second mold layer.

Example 5: the electronic package of Example 4, further comprising: a through mold via through the second mold layer, wherein the through mold via is coupled to the via.

Example 6: the electronic package of Examples 1-5, further comprising: a first die on the mold layer; and a second die on the mold layer, wherein the first die is communicatively coupled to the second die by the bridge.

Example 7: the electronic package of Example 6, wherein the first die is coupled to pads on the mold layer with a first level interconnect (FLI), and wherein the FLI is aligned with the via.

Example 8: the electronic package of Example 6, wherein the via and the shell are part of a power circuitry for the first die.

Example 9: the electronic package of Examples 1-8, wherein the via is a plated through hole via.

Example 10: the electronic package of Examples 1-9, wherein the via is a laser through hole via.

Example 11: an electronic package, comprising: a package substrate; a patch over the package substrate, wherein the patch comprises: a core, wherein the core comprises an organic material; a mold layer over the core; a bridge embedded in the mold layer; a column through the mold layer; and a via through a thickness of the core, wherein the via is aligned with the column; a first die coupled to the patch; and a second die coupled to the patch, wherein the first die is communicatively coupled to the second die by the bridge.

Example 12: the electronic package of Example 11, further comprising: a shell around the via, wherein the shell comprises a magnetic material.

Example 13: the electronic package of Example 12, wherein the via is part of a power circuitry for the first die.

Example 14: the electronic package of Examples 11-13, wherein the bridge comprises through substrate vias.

Example 15: the electronic package of Example 14, wherein a backside of the bridge is coupled to a plurality of pads on a surface of the core.

Example 16: the electronic package of Examples 11-15, wherein the first die is coupled to pads on the mold layer with a first level interconnect (FLI), and wherein the FLI is aligned with the via.

Example 17: the electronic package of Examples 11-16, further comprising: a second mold layer below the core; and a solder resist layer on the second mold layer.

Example 18: an electronic system, comprising: a board; a package substrate coupled to the board; a patch over the package substrate, wherein the patch comprises: a core, wherein the core comprises an organic material; a mold layer over the core; a bridge embedded in the mold layer; a column through the mold layer; and a via through a thickness of the core, wherein the via is aligned with the column; a first die coupled to the patch; and a second die coupled to the patch, wherein the first die is communicatively coupled to the second die by the bridge.

Example 19: the electronic system of Example 18, further comprising: a shell around the via, wherein the shell comprises a magnetic material.

Example 20: the electronic system of Example 18 or Example 19, wherein the first die is coupled to pads on the mold layer with a first level interconnect (FLI), and wherein the FLI is aligned with the via.

What is claimed is:

1. An electronic package, comprising:
a core, wherein the core comprises an organic material;
a via through a thickness of the core;
a shell around the via, wherein the shell comprises a magnetic material;
a mold layer over the core;
a bridge embedded in the mold layer; and
a column through the mold layer, wherein the column is aligned with the via.

2. The electronic package of claim 1, wherein the bridge comprises through substrate vias.

3. The electronic package of claim 2, wherein a backside of the bridge is coupled to a plurality of pads on a surface of the core.

4. The electronic package of claim 1, further comprising:
a second mold layer below the core; and
a solder resist layer on the second mold layer.

5. The electronic package of claim 4, further comprising:
a through mold via through the second mold layer, wherein the through mold via is coupled to the via.

6. The electronic package of claim 1, further comprising:
a first die on the mold layer; and
a second die on the mold layer, wherein the first die is communicatively coupled to the second die by the bridge.

7. The electronic package of claim 6, wherein the first die is coupled to pads on the mold layer with a first level interconnect (FLI), and wherein the FLI is aligned with the via.

8. The electronic package of claim 6, wherein the via and the shell are part of a power circuitry for the first die.

9. The electronic package of claim 1, wherein the via is a plated through hole via.

10. The electronic package of claim 1, wherein the via is a laser through hole via.

11. An electronic package, comprising:
a package substrate;
a patch over the package substrate, wherein the patch comprises:
a core, wherein the core comprises an organic material;
a mold layer over the core;
a bridge embedded in the mold layer;
a column through the mold layer; and
a via through a thickness of the core, wherein the via is aligned with the column;
a first die coupled to the patch; and
a second die coupled to the patch, wherein the first die is communicatively coupled to the second die by the bridge.

12. The electronic package of claim 11, further comprising:
a shell around the via, wherein the shell comprises a magnetic material.

13. The electronic package of claim 12, wherein the via is part of a power circuitry for the first die.

14. The electronic package of claim 11, wherein the bridge comprises through substrate vias.

15. The electronic package of claim 14, wherein a backside of the bridge is coupled to a plurality of pads on a surface of the core.

16. The electronic package of claim 11, wherein the first die is coupled to pads on the mold layer with a first level interconnect (FLI), and wherein the FLI is aligned with the via.

17. The electronic package of claim 11, further comprising:
a second mold layer below the core; and
a solder resist layer on the second mold layer.

18. An electronic system, comprising:
a board;
a package substrate coupled to the board;
a patch over the package substrate, wherein the patch comprises:
a core, wherein the core comprises an organic material;
a mold layer over the core;
a bridge embedded in the mold layer;
a column through the mold layer; and
a via through a thickness of the core, wherein the via is aligned with the column;
a first die coupled to the patch; and
a second die coupled to the patch, wherein the first die is communicatively coupled to the second die by the bridge.

19. The electronic system of claim 18, further comprising:
a shell around the via, wherein the shell comprises a magnetic material.

20. The electronic system of claim 18, wherein the first die is coupled to pads on the mold layer with a first level interconnect (FLI), and wherein the FLI is aligned with the via.
